(19) United States
(12) Patent Application Publication
(10) Pub. No.: US 2021/0123134 A1
(43) Pub. Date: Apr. 29, 2021

(54) SUBLIMATION AMPOULE WITH LEVEL SENSING

(71) Applicant: ENTEGRIS, INC., Billerica, MA (US)

(72) Inventors: John N. GREGG, Marble Falls, TX (US); Scott L. BATTLE, Cedar Park, TX (US); Donn NAITO, Meadowlakes, TX (US)

(21) Appl. No.: 16/682,658

(22) Filed: Nov. 13, 2019

Related U.S. Application Data
(60) Provisional application No. 62/925,313, filed on Oct. 24, 2019.

(51) Int. Cl. C23C 16/448; G01F 23/292; G01F 23/26

(52) U.S. Cl. CPC C23C 16/4481; G01F 23/265; G01F 23/2921

(57) ABSTRACT

A solids delivery ampule includes an ampule body defining an interior space. The interior space contains one or more solids support, and each solids support configured to support a quantity of a sublimation solid. The solids delivery ampule also includes a vapor outlet ports, one or more level sensor ports, and one or more level sensors. Each of the one or more level sensors extending through the one or more level sensor port into the interior space. Each of the one or more level sensors measures the quantity of the sublimation solid in each solids support.

### FIELD

This disclosure is directed to ampoules for providing sublimated solids for vapor deposition, particularly ampoules including level sensors for the sublimation solids.

### BACKGROUND

Ampoules containing a sublimation solid are used to supply a vapor in some vapor deposition tools. The vapor deposition tools use the supplied vapor, for example to deposit materials during the manufacture of, for example, semiconductor wafers. The vapor deposition tools may use deposition techniques, for example atomic layer deposition (ALD), plasma-enhanced chemical vapor deposition (PECVD), low-pressure chemical vapor deposition (LPCVD) or any combination of deposition methodologies. Current ampoules include one or more surfaces, trays, or compartments to support powder, polycrystalline, or compressed forms of the sublimation solid, which sublimates to a vapor when the ampoule is heated. As vapor is provided to the deposition tool, the sublimation solid is consumed. Typically, ampoules are used for amounts of time based on predictions or models of consumption of the solids included therein. Should a sublimation solid run out during wafer processing, it may result in the wafers being scrapped.

### SUMMARY

This disclosure is directed to ampoules for providing sublimated solids for vapor deposition, particularly ampoules including level sensors for the sublimation solids.

By providing sensors for at least a critical level or compartment within the ampoule, ampoule change-outs can be more precisely timed to avoid wasting sublimation solids or running out and failing to properly deposit the sublimated solids onto semiconductor wafers during manufacture. Further, by actually sensing levels of sublimation solids within the ampoule, the change-out time can be more accurately measured, or warnings provided when an ampoule is low on material. Warning levels could be provided at, for example, 50%, 20%, and/or 10% of material remaining.

In an embodiment, a solids delivery ampoule includes an ampoule body and lid defining an interior space. The interior space contains one or more solids support, and each solids support configured to support a quantity of a sublimation solid. The solids delivery ampoule also includes a vapor outlet ports, one or more level sensor ports, and one or more level sensors. Each of the one or more level sensors extending through the one or more level sensor port into the interior space. Each of the one or more level sensors measures the quantity of the sublimation solid in each solids support.

In an embodiment, the one or more level sensors are selected from a reed switch sensor, an optical sensor, an ultrasonic sensor, a capacitance sensor, an infrared sensor, or a radar sensor.

In an embodiment, the one or more level sensors each are a reed switch sensor comprising a magnetic disc, and a rod, wherein the rod includes one or more reed switches and the magnetic disc rests on a surface of the quantity of sublimation solid measured by the level sensor. In an embodiment, the rod of each of the reed switch sensors includes at least two reed switches.

In an embodiment, the one or more solids supports is a tray.

In an embodiment, the one or more solids supports are one or more spaces in a tray defined by one or more dividers.

In an embodiment, the solids delivery ampoule further includes one or more vent tubes configured to convey vapor upwards from at least one of the one or more solids supports.

In an embodiment, the one or more solids supports are one or more trays. In an embodiment, the one or more level sensors measure quantities of the sublimation solid in one or more trays selected from the one or more trays, wherein the one or more trays are selected based on a rate of consumption of the sublimation solids in each of the one or more trays. In an embodiment, the rate of consumption of the sublimation solids is determined based on the sublimation solid and a temperature applied to the solids delivery ampoule when providing a vapor of the sublimation solid. In an embodiment, the solids delivery ampoule includes fewer level sensors than a number of trays of the one or more trays.

In an embodiment, the solids delivery ampoule further includes a carrier gas inlet.

In an embodiment, the one or more level sensor port is one or more level sensor ports, and the one or more level sensor ports are all distributed along one straight line.

In an embodiment, the one or more level sensor port is one or more level sensor ports, and the one or more level sensor ports are all distributed such that the one or more level sensor ports do not form one straight line.

In an embodiment, the solids delivery ampoule further includes a controller. The controller is configured to receive a level signal from each of the one or more level sensors, determine whether the solids delivery ampoule is to be replaced based on the level signals received from each of the one or more level sensors. In an embodiment, the controller is further configured to direct the presentation of a message when the solids delivery ampoule is to be replaced. In an embodiment, the controller is further configured to direct a heater to pre-heat another ampoule. In an embodiment, the controller is further configured to direct an automatic switching from the solids delivery ampoule to another ampoule. In an embodiment, the controller is further configured to direct a purge sequence or a cooldown sequence to be performed on the solids delivery ampoule.

In an embodiment, a method of preparing a solids delivery ampoule includes providing a solids delivery ampoule, the solids delivery ampoule including an ampoule body and a lid defining an internal space containing one or more solids support, a vapor outlet port, and one or more level sensor port, adding one or more sublimation solids to each of the one or more solids supports, and providing a level sensor through each of the one or more level sensor ports.

In an embodiment, the level sensor is a reed switch sensor including a rod and a magnetic disc, and providing the level sensor includes placing the magnetic disc on a surface of one of the one or more sublimation solids.

In an embodiment, providing the level sensor through each of the one or more level sensor ports is performed under positive pressure.

In an embodiment, the method further includes sealing the solids delivery ampoule.

In an embodiment, there are fewer level sensor ports than solids supports. In an embodiment, the level sensors are provided to one or more solids supports, the one or more solids supports selected based on a rate of consumption of the sublimation solid for each of the solids supports.

In an embodiment, a method for delivering a vapor includes heating a solids delivery ampoule, measuring a level of a sublimation solid in a solids support via a level sensor located within the solids delivery ampoule, and providing a message based the level of the sublimation solid.

In an embodiment, the method further includes providing a flow of a carrier gas into the solids delivery ampoule.

In an embodiment, the level sensor is a reed switch sensor including a magnetic disc and one or more reed switches disposed on a rod.

In an embodiment, the method further includes measuring a second level of the sublimation solid in a second solids support via a second level sensor located within the solids delivery ampoule, and wherein the alert is further based on the second level of the second sublimation solid.

In an embodiment, the message includes an alert provided to a user.

In an embodiment, the message includes a command directing a heater to pre-heat another ampoule.

In an embodiment, the message includes a command directing an automatic switching from the solids delivery ampoule to another ampoule.

In an embodiment, the message includes a command directing a purge sequence or a cooldown sequence to be performed on the solids delivery ampoule.

In an embodiment, the solids delivery ampoule comprises a plurality of solids supports, and one or more solids supports where the level of the sublimation solid is measured are selected based on a predicted consumption of each of the one or more sublimation solids.

### DRAWINGS

FIG. 1 shows a sectional view of a solids delivery ampoule according to an embodiment.

FIG. 2 shows a sectional view of solids delivery ampoule according to an embodiment.

FIG. 3 shows a top view of a solids delivery ampoule according to an embodiment.

FIG. 4 shows a top view of a solids delivery ampoule according to an embodiment.

FIG. 5 shows a flowchart of a method for preparing a solids delivery ampoule according to an embodiment.

FIG. 6 shows a flowchart of a method for delivering a vapor according to an embodiment.

### DETAILED DESCRIPTION

This disclosure is directed to ampoules for providing sublimated solids for vapor deposition, particularly ampoules including level sensors for the sublimation solids.

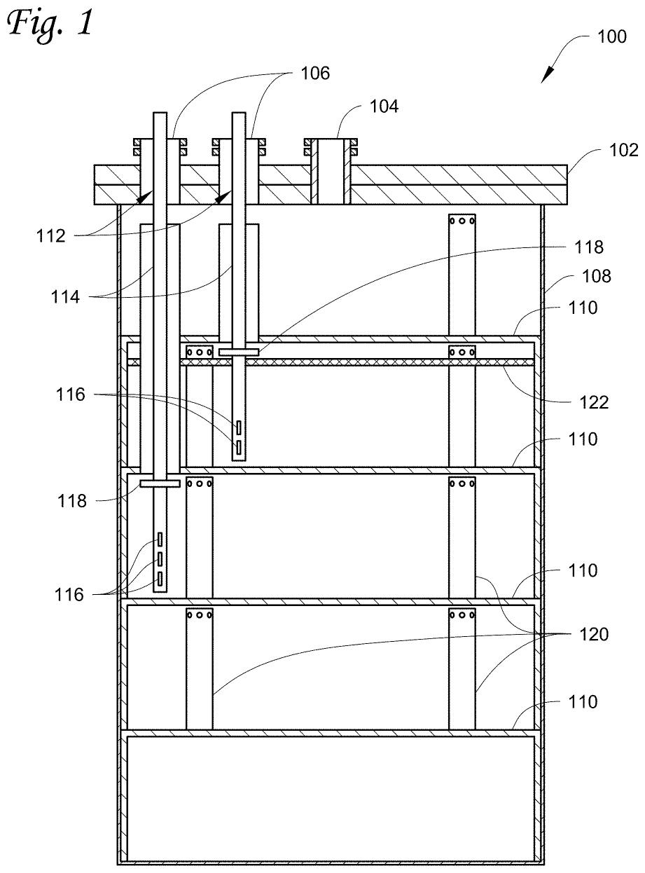

FIG. 1 shows a sectional view of a solids delivery ampoule according to an embodiment. Ampoule 100 includes a lid 102 including vapor outlet 104 and one or more sensor apertures 106. Ampoule lid 102 is joined to ampoule body 108. Ampoule body 108 includes one or more solids supports 110. Each of sensor apertures 106 allows a sensor 112 to be provided for one of the one or more solids supports 110. The sensors 112 may each be a reed switch sensor, including a shaft 114, one or more reed switches 116 located along the shaft, and a magnetic disc 118. The ampoule body may further contain one or more vapor venting channels 120 configured to allow vapor to circulate through the ampoule 100 and towards the vapor outlet 104.

Ampoule 100 is an ampoule used with a vapor deposition system to provide a vapor derived from a solid material. Ampoule 100 contains one or more sublimation solids in one or more solids supports 110. Ampoule 100 is configured to be heated when connected to a vapor deposition tool, such that conditions within ampoule 100 allow sublimation of the one or more sublimation solids.

Lid 102 covers an end of ampoule body 108. Lid 102 and ampoule body 108 define an internal space. Lid 102 may be sealed to ampoule body 108 such that all flow into and out of the internal space occurs through the vapor outlet 104. Lid 102 includes vapor outlet 104 and one or more sensor apertures 106.

Vapor outlet 104 is an outlet provided in lid 102 that is configured to allow vapor to exit ampoule 100. Vapor outlet 104 may include features for establishing a connection with a vapor deposition tool, for example a connection to a vapor line of the vapor deposition tool. Vapor outlet 104 may include a valve configured to regulate flow through the vapor outlet 104. In an embodiment, the valve included in vapor outlet 104 may be controlled by a controller included in ampoule 100. In an embodiment, the valve included in vapor outlet 104 may be controlled by a vapor deposition tool that ampoule 100 is used with. Vapor outlet 104 allows vapor including the sublimated sublimation solid to pass into the vapor deposition tool when ampoule 100 is in use.

Lid 102 also includes one or more sensor apertures 106. Sensor apertures 106 may be joined to the lid 102 by, for example, a weld or other suitable leak-tight joint. The sensor apertures 106 each allow a sensor 112 to be inserted such that it is within an internal space defined by lid 102 and ampoule body 108. The sensor apertures may include features allowing the sensors 112 to be fixed at the sensor apertures 106, such as, for example, threading. The sensor apertures may further include features allowing sealing when the sensors are fixed in the sensor apertures 106, such as, for example, o-rings, metal or elastomeric gaskets, or any other suitable leak-tight seal. In an embodiment, the seal may be formed at threading where sensors 112 are fixed to the sensor apertures 106. The seals used in the ampoule 100, including seals at sensor apertures 106 and also the seal between lid 102 and ampoule body 108 must be suitable for semiconductor processing. Suitable leak rates for such ampoules may be less than 4.0×10⁻⁹ sccs Helium. The leak rate may be measured by a Helium leak detector using an mass spectrometer.

Ampoule body 108 defines an internal space when joined to lid 102. Ampoule body 108 may be, for example, cylindrical in shape. Ampoule body 108 may be heated by a heater, for example, a dedicated oven, a heating jacket, or other suitable heaters. The heater may be included in the vapor deposition tool, or part of a separate system. The heat from the heater may be conducted by radiation, conduction, convection, or combinations thereof. The heater may provide one or more temperatures to one or more zones of the ampoule 100. Ampoule body 108 may be made of a thermally conductive material, such that heating of the ampoule body 108 increases a temperature within the internal space defined by ampoule body 108 such that sublimation solid within the internal space is heated. Ampoule body 108 may include features such as one or more flanges, lips, threadings, or other features so that lid 102 may be joined to ampoule body 108. These features may be provided at an open end of ampoule body 108. A seal may be provided where lid 102 is joined to ampoule body 108. The seal may be a separate component or integrated into one or both of lid 102 and ampoule body 108. The seal may be any suitable seal, such as, as non-limiting examples, an o-ring or a metal or elastomer flat gasket.

The internal space defined by ampoule body 108 and lid 102 contains one or more solids supports 110. In an embodiment, ampoule 100 includes one or more solids supports 110. The solids supports 110 may each be a platform, a tray, a section of a divided tray, or any other suitable support for a sublimation solid. The sublimation solids may be solids that are sublimated to provide a vapor for a vapor deposition process carried out by a vapor deposition too to which the ampoule 100 is connected. The vapor deposition tool may receive the vapor via the vapor outlet 104. Sublimation solids include, as non-limiting examples, AlCl₃, tungsten halides and oxyhalides including but not limited to WCl₅, WCl₆ and WOCl₄, molybdenum halides and oxyhalides including but not limited to MoCl₅, MoOCl₄, and MoO₂Cl₂, zirconium chlorides or oxyhalides including ZrCl₄, and hafnium chlorides or oxyhalides including HfCl₄. In an embodiment, the sublimation solid may be in the form of a powder, crystal, pellet, or puck. In an embodiment where multiple solids supports 110 are stacked on top of one another, at least some of the solids supports 110 may include one or more apertures each allowing one of sensors 112 to extend through the solids support 110 such that it may measure a level of sublimation solid in another of the solids supports 110. The apertures formed in solids supports 110 may also allow vapor to move through the internal space, for example towards vapor outlet 104. Sensor apertures 106 may be aligned with these apertures in the solids supports 110 such that sensors 112 extend from the sensor apertures 106 through these apertures.

One or more sensors 112 are provided within the internal space defined by lid 102 and ampoule body 108. The one or more sensors 112 each measure a level of a sublimation solid in one of the one or more solids supports 110. A sensor 112 is provided through each of the sensor apertures 106. Each of the sensors 112 may be fixed to lid 102 at the sensor aperture 106. A seal may be included where the sensor 112 is fixed to the sensor aperture 106, for example an o-ring, a flat gasket, or any other suitable seal. The seal may be a separate component fitted at the junction of sensor 112 and sensor aperture 106, an integral component of sensor 112, an integral feature at sensor aperture 106, or include combinations of such structures.

The one or more sensors 112 each extend from or through one of the one or sensor apertures 106 included in lid 102. Each sensor 112 may extend through one or more apertures provided in the solids supports 110 such that the sensor 112 has access to the solids support suitable to allow the sensor 112 to measure the level of sublimation solid. Access to a solids support 110 may include an absence of physical obstructions between sensor 112 and the sublimation solid to be measured. Access to a solids support 110 may include a path for an emission of the sensor to reach the sublimation solid and return to the sensor 112.

The one or more sensors 112 may include, for example, an optical sensor. In an embodiment, the one or more sensors 112 may include an ultrasonic sensor. In an embodiment, the one or more sensors may include a capacitance sensor. In an embodiment, the one or more sensors may include an infrared sensor. In an embodiment, the one or more sensors may include a radar sensor.

In an embodiment, each of the sensors 112 is a reed switch sensor. When sensors 112 are reed switch sensors, each includes a shaft 114, one or more reed switches 116 located along the shaft, and a magnetic disc 118.

Shaft 114 extends from the end of sensor 112 at or near the sensor aperture 106 towards a solids support where the sensor 112 measures the level of the sublimation solid. Shaft 114 may extend through one or more apertures formed in solids supports 110 as it extends towards the solids support 110 where the sensor 112 measures the level of the sublimation solid. Shaft 114 may include a retainer at or near an end configured to prevent magnetic disc 118 from passing the end of shaft 114 or preventing magnetic disc 118 from passing the reed switch 116 closest to that end. In an embodiment, shaft 114 may include an electromagnet configured to move magnetic disc 118, for example to move magnetic disc 118 towards the end of the sensor 112 at or near the sensor aperture 106 when the sensor 112 is not measuring a level of a sublimation solid.

Reed switch 116 is a switch configured to be operated provide a signal when a magnet is at or near its position along shaft 114. Reed switch 116 forms an electrical connection when the magnetic field of magnetic disc 118 acts upon it. An electrical signal from a particular reed switch 116 is indicative of the proximity of the magnetic disc 118. As magnetic disc 118 passes each of reed switches 116, it may close the reed switch 116, completing a circuit. Reed switch 116 is positioned on shaft 114. In an embodiment, shaft 114 has one or more reed switches disposed along its length. In an embodiment, the one or more reed switches are located near an end of the shaft 114 on an end of sensor 112 that is opposite the sensor aperture 106. The reed switches may be placed at positions along shaft 114 that correspond to particular levels of the sublimation solid in a solids support 110 that are important, for example being indicative of an imminent need to replace or end the use of ampoule 100 in a vapor deposition system. The positions may be predetermined distances from the solids support 110 when the solids support 110 and the sensor 112 are each in their operating positions when the ampoule 100 is assembled. The predetermined distance may be computed based on a level corresponding to a particular remaining operational period or quantity of sublimation solid in the solids support 110 measured by that particular sensor 112. In an embodiment, the sensor 112 includes one reed switch. In an embodiment, the sensor 112 includes a plurality of reed switches. In an embodiment, the sensor 112 includes three reed switches 116. In an embodiment, each of the plurality of reed switches 116 may correspond to a different level of the sublimation solid. In an embodiment, each reed switch 116 may be associated with a different status, message, or alert provided to a user of a vapor deposition system.

Magnetic disc 118 includes an opening sized to accommodate shaft 114, such that it surrounds and can slide with respect to the length of shaft 114. Magnetic disc 118 may be placed onto a surface of sublimation solids in the solids support 110 that the sensor 112 measures a level in. As the sublimation solids are consumed during a vapor deposition process, causing the upper surface of the sublimation solids to fall, the magnetic disc may move along shaft 114 and its position relative to the one or more reed switches 116 may change. Movement of magnetic disc 118 is detected by the one or more reed switches 116, which provide a level of the sublimation solid based on the position or movement of the magnetic disc 118. Magnetic disc 118 may be configured expand once passed through sensor aperture 106, for example by having a snap ring or spiral spring shape.

In an embodiment, a screen or open mesh 122 such as an open metal mesh may be placed on the solid material, and the magnetic disc 118 may rest on the mesh 122. The mesh 122 may rest on the sublimation solid, and lower as the sublimation solid is consumed. The mesh 122 may partially or entirely cover the upper surface of the sublimation solid. Mesh 122 may prevent submersion of the magnetic disc 118 in the sublimation solid. The level of mesh 122 may be a function of an area of the sublimation solid that is larger than an area of magnetic disc 118. The larger area covered by mesh 122 compared to magnetic disc 118 may allow for a more stable measurements of level.

The one or more sensors 112 may each include a wired or wireless connection to a controller. The controller may, for example, compare the sublimation solid level to a threshold, and based on the comparison, issue an alert through, as non-limiting examples, a display, play of an audio message, a communication to another device, or combinations thereof. In an embodiment, the controller is a controller of a vapor deposition tool that ampoule 100 is used with. In an embodiment, the controller is included on the ampoule 100. The wired or wireless connection allows the one or more sensors to communicate the level of a sublimation solid measured by that sensor 112. The controller may further provide control of additional aspects of ampoule 100 such as controlling flow through a valve at vapor outlet 104. In an embodiment, the controller is configured to receive a level signal from each of the one or more sensors 112, and determine whether the solids delivery ampoule is to be replaced based on the level signals received from each of the one or more level sensors. In an embodiment, the controller may direct the presentation of a message when the solids delivery ampoule 100 is to be replaced. In an embodiment, the controller may direct heating of a replacement ampoule. In an embodiment, the controller may direct automatic switching to the replacement ampoule. In an embodiment, the controller may direct purging and/or cooldown processes for the solids delivery ampoule 100 once it has been depleted.

Vapor venting channels 120 may be provided within the internal space. Vapor venting channels are configured to allow vapor to circulate through the ampoule 100 and towards the vapor outlet 104. In an embodiment, vapor venting channels are included in one or more of the solids supports 110. In an embodiment, vapor venting channels 120 are included in each of the solids supports 110. In an embodiment, vapor venting channels 120 are hollow tubes with open ends, such that vapor may enter at a first end and leave the vapor venting channel 120 at a second end. Vapor venting channels 120 may include additional openings to further facilitate flow of vapor within the internal space defined by ampoule body 108. In an embodiment, the vapor venting channels 120 may be formed of porous metal. In an embodiment, the vapor venting channels 120 may be closed at one or both ends, with holes drilled to allow flow through each vapor venting channel 120. In an embodiment, the vapor venting channels may be 3-D printed to provide openings.

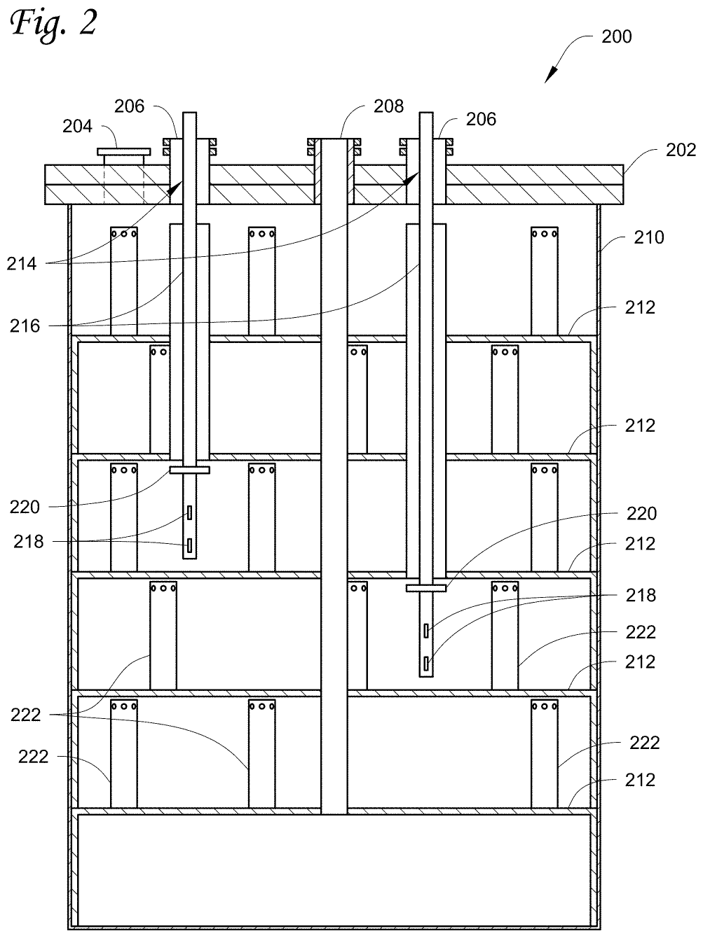

FIG. 2 shows a sectional view of solids delivery ampoule according to an embodiment. Ampoule 200 includes a lid 202 including vapor outlet 204 and one or more sensor apertures 206. In the embodiment shown in FIG. 2, ampoule 200 further includes carrier gas inlet 208. Ampoule lid 202 is joined to ampoule body 210. Ampoule body includes one or more solids supports 212. Each of sensor apertures 206 allows a sensor 212 to be provided for one of the one or more solids supports 212. The sensors 214 may each be a reed switch sensor, including a shaft 216, one or more reed switches 218 located along the shaft, and a magnetic disc 220. The ampoule body may further contain one or more vapor venting channels 222 configured to allow vapor and carrier gas to circulate through the ampoule 200 and towards the vapor outlet 204.

Ampoule 200 is an ampoule used with a vapor deposition system to provide a vapor derived from a solid material. Ampoule 200 contains one or more sublimation solids in one or more solids supports 212. Ampoule 200 is configured to be heated when connected to a vapor deposition tool, such that conditions within ampoule 200 allow sublimation of the one or more sublimation solids.

Lid 202 covers an end of ampoule body 210. Lid 202 and ampoule body 210 define an internal space. Lid 202 may be sealed to ampoule body 210 such that all flow into and out of the internal space occurs through the vapor outlet 204 or the carrier gas inlet 208. Lid 202 includes vapor outlet 204, carrier gas inlet 208, and one or more sensor apertures 206.

Vapor outlet 204 is an outlet provided in lid 202 that is configured to allow vapor and carrier gas to exit ampoule 200. Vapor outlet 204 may include features for establishing a connection with a vapor deposition tool, for example a connection to a vapor line of the vapor deposition tool. Vapor outlet 204 may include a valve configured to regulate flow through the vapor outlet 204. In an embodiment, the valve included in vapor outlet 204 may be controlled by a controller included in ampoule 200. In an embodiment, the valve included in vapor outlet 204 may be controlled by a vapor deposition tool that ampoule 200 is used with. Vapor outlet 204 allows vapor including the sublimated sublimation solid to pass into the vapor deposition tool when ampoule 200 is in use.

Lid 202 also includes one or more sensor apertures 206. The sensor apertures 206 each allow a sensor 214 to be inserted such that it is within an internal space defined by lid 202 and ampoule body 210. The sensor apertures may include features allowing the sensors to be fixed at the sensor apertures 206, such as, for example, threading. The sensor apertures may further include features allowing sealing when the sensors are fixed in the sensor apertures 206, such as, for example, o-rings, gaskets, or any other suitable seal. The seals used in the ampoule 200, including seals at sensor apertures 206 and also the seal between lid 202 and ampoule body 210 must be suitable for semiconductor processing. Suitable leak rates for such ampoules may be less than 4.0×10⁻⁹ sccs Helium. The leak rate may be measured by a Helium leak detector using an mass spectrometer. In ampoule 200, the sensor apertures 206 may be distributed such that sensors 214 are located within the internal space such that carrier gas flow is not disrupted.

Carrier gas inlet 208 is an inlet provided in lid 202. Carrier gas inlet 208 may connect to a source of carrier gas, such as a gas line from a vapor deposition tool or a carrier gas tank, or any other suitable source of carrier gas. The carrier gas may be, for example, an inert gas. In an embodiment, the carrier gas may be a reactive gas. Carrier gas inlet 208 may include a valve configured to regulate flow of the carrier gas into ampoule 200. Carrier gas inlet 208 may be connected to a carrier gas tube configured to convey the carrier gas within the internal space defined by lid 202 and ampoule body 210. In an embodiment, the carrier gas tube is configured to convey the carrier gas to an end of the internal space within ampoule body 210 that is opposite the lid 202.

In the embodiment shown in FIG. 2, the carrier gas flows from a bottom of ampoule 200 towards a top of ampoule 200. The carrier gas inlet 208 shown in FIG. 2 includes a dip tube conveying the carrier gas to the bottom of ampoule 200, and the vapor outlet 204 is in communication with the top of the internal space of ampoule 200, just below lid 202. In this embodiment, the carrier gas is provided at a bottom of the internal space of the ampoule and travels upwards through the ampoule 200, leaving, along with vapor of the sublimation solid, at vapor outlet 204. In an alternative embodiment, 204 may be used instead as the carrier gas inlet and 208 as the vapor outlet; in this embodiment, carrier gas flows downwards through the ampoule 200, and the vapor and carrier gas is taken up by the dip tube towards 208 where it exits ampoule 200.

Ampoule body 210 defines an internal space when joined to lid 202. Ampoule body 210 may be, for example, cylindrical in shape. Ampoule body 210 may be heated by a heater, for example, a dedicated oven, a heating jacket, or other suitable heaters. The heater may be included in the vapor deposition tool, or part of a separate system. The heat from the heater may be conducted by radiation, conduction, convection, or combinations thereof. The heater may provide one or more temperatures to one or more zones of the ampoule 200. Ampoule body 210 may be made of a thermally conductive material, such that heating of the ampoule body 210 increases a temperature within the internal space defined by ampoule body 210 such that sublimation solid within the internal space is heated. Ampoule body 210 may include features such as one or more flanges, lips, threadings, or other features so that lid 202 may be joined to ampoule body 210. These features may be provided at an open end of ampoule body 210. A seal may be provided where lid 202 is joined to ampoule body 210. The seal may be a separate component or integrated into one or both of lid 202 and ampoule body 210. The seal may be any suitable seal, such as, as non-limiting examples, an o-ring or a metal or elastomer flat gasket.

The internal space defined by ampoule body 210 and lid 102 contains one or more solids supports 212. In an embodiment, ampoule 200 includes one or more solids supports 212. The solids supports 212 may each be a platform, a tray, a section of a divided tray, or any other suitable support for a sublimation solid. The sublimation solids may be solids that are sublimated to provide a vapor for a vapor deposition process carried out by a vapor deposition too to which the ampoule 200 is connected. The vapor deposition tool may receive the vapor via the vapor outlet 204 Sublimation solids include, as non-limiting examples, AlCl₃, tungsten halides and oxyhalides including but not limited to WCl₅, WCl₆ and WOCl₄, molybdenum halides and oxyhalides including but not limited to MoCl₅, MoOCl₄, and MoO₂Cl₂, zirconium chlorides or oxyhalides including ZrCl₄, and hafnium chlorides or oxyhalides including HfCl₄. In an embodiment, the sublimation solid may be in the form of a powder, crystal, pellet, or puck. In an embodiment where multiple solids supports 212 are stacked on top of one another, at least some of the solids supports 212 may include one or more apertures each allowing one of sensors 214 to extend through the solids support 212 such that it may measure a level of sublimation solid in another of the solids supports 212. Sensor apertures 206 may be aligned with these apertures in the solids supports 212 such that sensors 214 extend from the sensor apertures 206 through these apertures.

One or more sensors 214 are provided within the internal space defined by lid 202 and ampoule body 210. The one or more sensors 214 each measure a level of a sublimation solid in one of the one or more solids supports 212. A sensor 214 is provided through each of the sensor apertures 206. Each of the sensors 214 may be fixed to lid 202 at the sensor aperture 206. A seal may be included where the sensor 214 is fixed to the sensor aperture 206, for example an o-ring, a flat gasket, or any other suitable seal. The seal may be a separate component fitted at the junction of sensor 214 and sensor aperture 206, an integral component of sensor 214, an integral feature at sensor aperture 206, or include combinations of such structures. Sensor 214, or a tube surrounding sensor 214, may be sealed where it passes through each of the solids supports 212, to prevent carrier gas from having an alternate path through the internal space of ampoule 200.

The one or more sensors 214 each extend from or through one of the one or sensor apertures 206 included in lid 202. Each sensor 214 may extend through one or more apertures provided in the solids supports 212 such that the sensor 214 has access to the solids support suitable to allow the sensor 214 to measure the level of sublimation solid. Access to a solids support 212 may include an absence of physical obstructions between sensor 214 and the sublimation solid to be measured. Access to a solids support 212 may include a path for an emission of the sensor to reach the sublimation solid and return to the sensor 214.

The one or more sensors 214 may include, for example, an optical sensor. In an embodiment, the one or more sensors 214 may include an ultrasonic sensor. In an embodiment, the one or more sensors may include a capacitance sensor. In an embodiment, the one or more sensors may include an infrared sensor. In an embodiment, the one or more sensors may include a radar sensor.

In an embodiment, each of the sensors 214 is a reed switch sensor. When sensors 214 are reed switch sensors, each includes a shaft 216, one or more reed switches 218 located along the shaft, and a magnetic disc 220.

Shaft 216 extends from the end of sensor 214 at or near the sensor aperture 206 towards a solids support where the sensor 214 measures the level of the sublimation solid. Shaft 216 may extend through one or more apertures formed in solids supports 212 as it extends towards the solids support 212 where the sensor 214 measures the level of the sublimation solid. In an embodiment, shaft 216 may include an electromagnet configured to move magnetic disc 220, for example to move magnetic disc 220 towards the end of the sensor 214 at or near the sensor aperture 206 when the sensor 214 is not measuring a level of a sublimation solid.

Reed switch 218 is a switch configured to be operated such that it provides a signal when a magnet is at or near its position along shaft 216. Reed switch 218 forms an electrical connection when the magnetic field of magnetic disc 220 acts upon it. An electrical signal from a particular reed switch 218 is indicative of the proximity of the magnetic disc 220. Reed switch 218 is positioned on shaft 216. In an embodiment, shaft 216 has one or more reed switches disposed along its length. In an embodiment, the one or more reed switches are located near an end of the shaft 216 on an end of sensor 214 that is opposite the sensor aperture 206. The reed switches may be placed at positions along shaft 216 that correspond to particular levels of the sublimation solid in a solids support 212 that are important, for example being indicative of an imminent need to replace or end the use of ampoule 200 in a vapor deposition system. The positions may be predetermined distances from the solids support 212 when the solids support 212 and the sensor 214 are each in their operating positions when the ampoule 200 is assembled. The predetermined distance may be computed based on a level corresponding to a particular remaining operational period or quantity of sublimation solid in the solids support 212 measured by that particular sensor 214. In an embodiment, the sensor 214 includes one reed switch. In an embodiment, the sensor 214 includes a plurality of reed switches. In an embodiment, the sensor 214 includes three reed switches 218. In an embodiment, each of the plurality of reed switches 218 may correspond to a different level of the sublimation solid. In an embodiment, each reed switch 218 may be associated with a different status, message, or alert provided to a user of a vapor deposition system.

Magnetic disc 220 includes an opening sized to accommodate shaft 216, such that it surrounds and can slide with respect to the length of shaft 216. Magnetic disc 220 may be placed onto a surface of sublimation solids in the solids support 212 that the sensor 214 measures a level in. As the sublimation solids are consumed during a vapor deposition process, causing the upper surface of the sublimation solids to fall, the magnetic disc may move along shaft 216 and its position relative to the one or more reed switches 218 may change. Movement of magnetic disc 220 is detected by the one or more reed switches 218, which provide a level of the sublimation solid based on the position or movement of the magnetic disc 220. Magnetic disc 220 may be configured expand once passed through sensor aperture 206, for example by having a snap ring or spiral spring shape.

The one or more sensors 214 may each include a wired or wireless connection to a controller. The controller may, for example, compare the sublimation solid level to a threshold, and based on the comparison, issue an alert through, as non-limiting examples, a display, play of an audio message, a communication to another device, or combinations thereof. In an embodiment, the controller is a controller of a vapor deposition tool that ampoule 200 is used with. In an embodiment, the controller is included on the ampoule 200. The wired or wireless connection allows the one or more sensors to communicate the level of a sublimation solid measured by that sensor 214. The controller may further provide control of additional aspects of ampoule 200 such as controlling flow through a valve at vapor outlet 204, controlling flow through carrier gas inlet 208, or combinations thereof. In an embodiment, the controller is configured to receive a level signal from each of the one or more sensors 214, and determine whether the solids delivery ampoule is to be replaced based on the level signals received from each of the one or more level sensors. In an embodiment, the controller may direct the presentation of a message when the solids delivery ampoule 200 is to be replaced. In an embodiment, the controller may direct heating of a replacement ampoule. In an embodiment, the controller may direct automatic switching to the replacement ampoule. In an embodiment, the controller may direct purging and/or cooldown processes for the solids delivery ampoule 200 once it has been depleted.

Vapor venting channels 222 may be provided within the internal space. Vapor venting channels are configured to allow vapor to circulate through the ampoule 200 and towards the vapor outlet 204. In an embodiment, vapor venting channels are included in solids supports 212. In an embodiment, vapor venting channels 222 are included in each solids support 212 except for a bottom-most solids support included within ampoule 200. Vapor venting channels 222 may be hollow tubes with open ends, such that vapor may enter at a first end and leave the vapor venting channel 222 at a second end. Vapor venting channels 222 may include additional openings to further facilitate flow of the vapor and carrier gas through the internal space defined by ampoule body 210. In an embodiment, each of solids supports 212 includes a plurality of vapor venting channels distributed with even density across the surface area of the solids support 212.

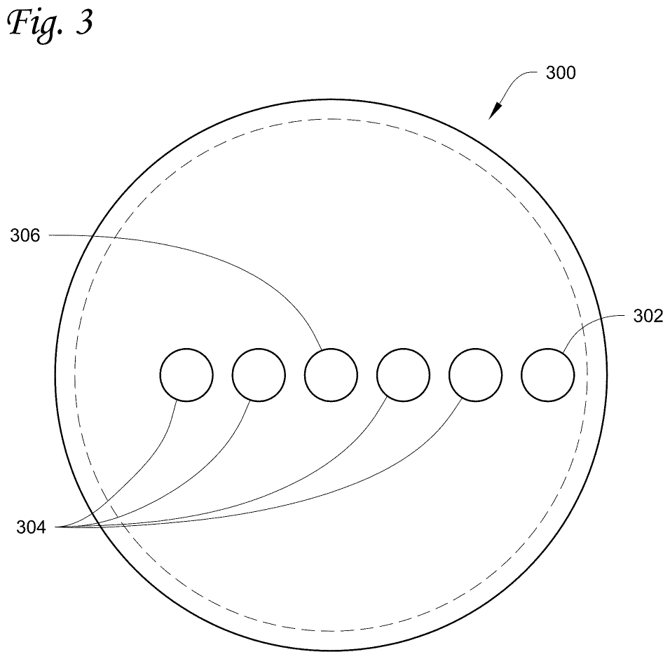

FIG. 3 shows a top view of a solids delivery ampoule according to an embodiment. In the top view of FIG. 3, ampoule lid 300 is visible. Ampoule lid 300 is a cover placed on an ampoule body to close a solids delivery ampoule. Ampoule lid 300 may be, for example, lid 102 or lid 202 described above. Ampoule lid 300 includes a vapor outlet 402, one or more sensor apertures 304, and a carrier gas inlet 306.

Vapor outlet 302 is an outlet through which vapor passes through ampoule lid 300, such as vapor outlet 104 or vapor outlet 204 described above. Vapor outlet 302 may be connected to a vapor line of a vapor deposition tool. Vapor outlet 302 may include a controllable valve regulating flow through vapor outlet 302. In an embodiment, the vapor outlet 302 is connected to a mass flow controller (MFC) or a mass flow meter (MFM) in either the deposition tool or in a separate solid delivery system.

Sensor apertures 304 are openings in ampoule lid 300 through which sensors extend into the internal space of an ampoule including ampoule lid 300. The sensor apertures 304 may be the one or more sensor apertures 106 or the one or more sensor apertures 206 described above. The sensor apertures 304 may include features for securing sensors in the sensor apertures, such as threading on an outer or inner surface of the sensor apertures 304. In an embodiment, the sensors are attached to welded fittings where the sensor aperture 304 and the sensor have mating, rotatable threads that compress a metal gasket to form a leak tight seal.

Carrier gas inlet 306 is an inlet for a carrier gas, such as carrier gas inlet 208 described above. In an embodiment, carrier gas inlet 306 may be absent, or may be replaced by another sensor aperture 304.

In the embodiment shown in FIG. 3, the vapor outlet 302, sensor apertures 304, and carrier gas inlet 306 are arranged in a single straight line. The embodiment shown in FIG. 3 may be used, for example, to enable the fit of an ampoule including ampoule lid 300 within a particular vapor deposition tool, depending on the configuration of the vapor deposition tool and the connection points for the carrier gas inlet 306 and the vapor outlet 302 provided by the vapor deposition tool. The straight-line arrangement of the embodiment shown in FIG. 3 may facilitate use of a two-piece heater such as a heating jacket surrounding the ampoule lid 300 and an ampoule body to which it is attached.

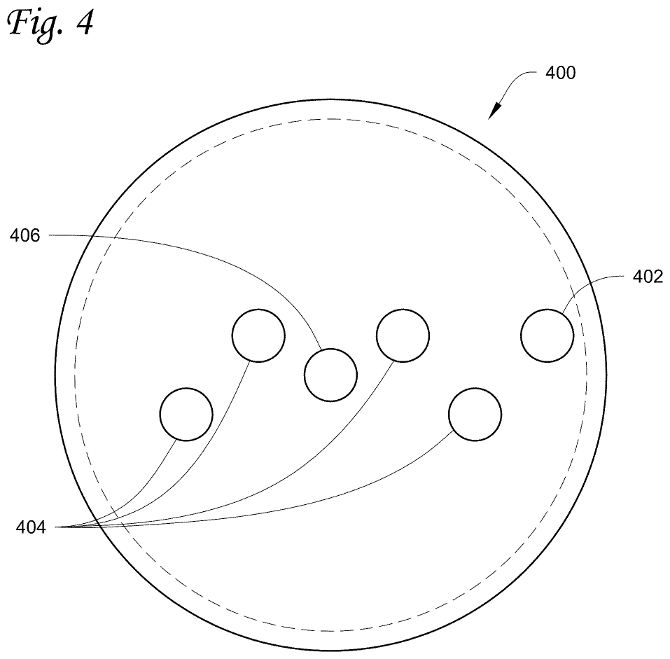

FIG. 4 shows a top view of a solids delivery ampoule according to an embodiment. In the top view of FIG. 4, ampoule lid 400 is visible. Ampoule lid 400 is a cover placed on an ampoule body to close a solids delivery ampoule. Ampoule lid 400 may be, for example, a lid 102 or lid 202 described above. Ampoule lid 400 includes a vapor outlet 402, one or more sensor apertures 404, and a carrier gas inlet 406.

Vapor outlet 402 is an outlet through which vapor passes through ampoule lid 400, such as vapor outlet 104 or vapor outlet 204 described above. Vapor outlet 402 may be connected to a vapor line of a vapor deposition tool. Vapor outlet 402 may include a controllable valve regulating flow through vapor outlet 402.

Sensor apertures 404 are openings in ampoule lid 400 through which sensors extend into the internal space of an ampoule including ampoule lid 400. The sensor apertures 404 may be the one or more sensor apertures 106 or the one or more sensor apertures 206 described above. The sensor apertures 404 may include features for securing sensors in the sensor apertures, such as threading on an outer or inner surface of the sensor apertures 404. In an embodiment, the sensors are attached to welded fittings where the sensor aperture 404 and the sensor have mating, rotatable threads that compress a metal gasket to form a leak tight seal.

Carrier gas inlet 406 is an inlet for a carrier gas, such as carrier gas inlet 208 described above. In an embodiment, carrier gas inlet 406 may be absent, or may be replaced by another sensor aperture 404.

The arrangement of the vapor outlet 402, the one or more sensor apertures 404, and the carrier gas inlet 406 shown in FIG. 4 may be such that there is space to manipulate components at any of the vapor outlet 402, the one or more sensor apertures 404, and the carrier gas inlet 406. For example, where the sensors are secured in sensor apertures 404 by threaded connections, the vapor outlet 402, the one or more sensor apertures 404, and the carrier gas inlet 406 may be spaced apart by at least an inch to allow hands or tools such as wrenches to access and manipulate the connection at the sensor apertures 404. The staggered layout of the embodiment shown in FIG. 4 may require a heating jacket to be custom-made to fit the arrangement of the sensor apertures 404.

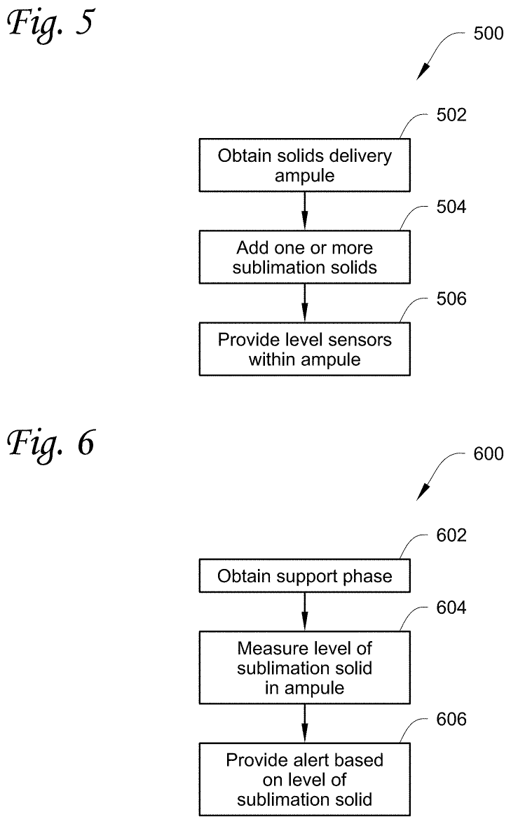

FIG. 5 shows a flowchart of a method for preparing a solids delivery ampoule according to an embodiment. Method 500 includes obtaining a solids delivery ampoule 502, adding one or more sublimation solids 504, and providing a level sensor through each level sensor port 506.

A solids delivery ampoule is obtained at 502. The solids delivery ampoule may be, for example, ampoule 100 or ampoule 200 as described above. The solids delivery ampoule obtained at 502 includes one or more sensor ports, such as sensor apertures 104 or 204 described above. The ampoule may include lid 102 or lid 202 described above and an ampoule body such as ampoule body 108 or ampoule body 210 described above. The ampoule obtained at 502 may optionally include a carrier gas inlet, such as carrier gas inlet 208 described above.

One or more sublimation solids are added to the ampoule at 504. The sublimation solids may include one or more, as non-limiting examples, AlCl₃, tungsten halides and oxyhalides including but not limited to WCl₅, WCl₆ and WOCl₄, molybdenum halides and oxyhalides including but not limited to MoCl₅, MoOCl₄, and MoO₂Cl₂, zirconium chlorides or oxyhalides including ZrCl₄, and hafnium chlorides or oxyhalides including HfCl₄. In an embodiment, the sublimation solid may be in the form of a powder, crystal, pellet, or puck. The sublimation solids may be placed in or one or more solids supports, such as trays, plates, compartments, segments of a divided support, or any other such suitable support. The solids supports may be assembled, for example layers of trays or compartments, as each solids support is filled with the sublimation solids. The filling with sublimation solids at 504 may include adding sublimation solids to achieve a predetermined level, addition of a predetermined mass of the sublimation solid, or any other suitable method of providing a desired quantity of the sublimation solid to the solids supports within the ampoule.

A level sensor through is provided through each level sensor port at 506. The level sensors may be provided prior to or following attachment of the lid to the ampoule body. Each level sensor provided at 506 is provided in a position where it can determine a level of a sublimation solid within the ampoule. Each level sensor provided at 506 may measure a level in a different solids support within the ampoule. In an embodiment, multiple level sensors may measure levels of sublimation solid at different points in one solids support. The level sensors may be, as non-limiting examples, reed switch sensors, optical sensors, ultrasonic sensors, capacitance sensors, infrared sensors, radar sensors, or any combination thereof. In an embodiment, the level sensors provided at 506 are reed switch sensors including a shaft, one or more reed switches disposed along the shaft, and a magnetic disc. In this embodiment, providing the level sensors includes placing the magnetic disc of each reed switch sensor onto a surface of a sublimation solid added at 504. A seal may be provided to seal the interior of the ampoule when the sensors are provided at 506, for example by an o-ring, flat gasket, or other such suitable seal located at the connection between the level sensor and the level sensor port. When the level sensor is provided at 506 and the lid is attached to the ampoule body, the ampoule is sealed and suitable for transport and for use, such as providing a vapor of the sublimation solid to a vapor deposition tool. While in use, the sensors provided at 506 can provide measurements of levels of sublimation solids within the ampoule prepared according to method 500.

FIG. 6 shows a flowchart of a method for delivering a vapor according to an embodiment. Method 600 includes heating a solids delivery ampoule 602, measuring a level of a sublimation solid in the solids delivery ampoule using a level sensor within the solids delivery ampoule 604, and providing an alert based on the level of the sublimation solid 606.

Heating a solids delivery ampoule is carried out at 602. The solids delivery ampoule, such as ampoule 100 or ampoule 200 described above, is heated, for example by a heater, for example, a dedicated oven, a heating jacket, or other suitable heaters. The heater may be included in the vapor deposition tool, or part of a separate system. The heat from the heater may be conducted by radiation, conduction, convection, or combinations thereof. The heater may provide one or more temperatures to one or more zones of the ampoule. The heating produces a temperature within the solids delivery ampoule sufficient to allow sublimation of the sublimation solid within the solids delivery ampoule. In an embodiment, a carrier gas may be supplied to the ampoule while the solids delivery ampoule is heated at 602. The sublimation solids sublimate into vapor over time while the ampoule is heated at 602. The vapor from the sublimation of the sublimation solid may be provided to a vapor deposition tool, for example by a vapor outlet such as vapor outlet 104 or vapor outlet 204 described above. In some embodiments, the vapor may be accompanied by carrier gas supplied to the ampoule.

The level of a sublimation solid in the solids delivery ampoule is measured using a level sensor within the solids delivery ampoule at 604. The level sensor may be provided within the solids delivery ampoule through an aperture provided in a lid of the ampoule. The level sensor may be measuring a level of one sublimation solid in a solids support, such as solids support 110 or 212. When there are multiple solids supports, and the number of sensors is less than the number of solids supports, the solids supports selected for measurement by the level sensors may be selected based on, for example, quantity and/or type of sublimation solid held in the solids support, predictions of consumption of the sublimation solid included in the solids support, or combinations of such factors. The level sensor may be an optical sensor, an ultrasonic sensor, a capacitance sensor, an infrared sensor, or a radar sensor. In an embodiment, the level sensor is a reed switch sensor including a shaft, one or more reed switches disposed on the shaft, and a magnetic disc surrounding the shaft. The magnetic disc may rest on the sublimation solids in the solids support. The position of the magnetic disc with respect to the reed switches may provide the level of the sublimation solid measured at 604.

Based on a level of a sublimation solid, message is provided at 606. In an embodiment, the message may be provided when the level of sublimation solid measured at 604 is below an alert threshold. In an embodiment, multiple sublimation solids may have their levels measured, and if any are below an alert threshold, the alert is provided 606. In an embodiment, the multiple sublimation solids each have their own distinct alert thresholds. In an embodiment, the multiple sublimation solids each have the same alert threshold. In an embodiment, the sublimation solids whose level is compared to an alert threshold is selected based on for example, quantity and/or type of sublimation solid held in the solids support, predictions of consumption of the sublimation solid included in the solids support, or combinations of such factors. In an embodiment, the alert threshold is indicative of a need to change the solids delivery ampoule or to end a vapor deposition process. Providing the message may be based on application and delivery conditions, such as flow rates of vapor exiting the ampoule (for example, by mass or by volume), temperatures provided to the ampoule, flow rates of carrier gas into the ampoule (for example, by mass or volume). In an embodiment, the message is an alert provided a user through one or more of a display of a message, playing of an audio alert, and/or sending a notification to a device such as a tablet, mobile phone, or other portable device. The alert may identify an ampoule connected to where the alert was triggered, in embodiments where multiple solids delivery ampoules are connected to a vapor deposition tool. In an embodiment, the message may be to another device, such as a command directing an activity at that device. As non-limiting examples, messages to other devices may direct the ampoule to begin a purge and/or a cooldown process, may direct the vapor deposition tool or another system to begin an automated ampoule switching process, or may direct the vapor deposition tool or another system to operate a heater to heat another ampoule, for example to prepare this other ampoule for use such as being switched to from the ampoule for which the alert was generated.

Aspects:

It is understood that any of aspects 1-19 can be combined with any of aspects 20-25 or 26-33. It is understood that any of aspects 20-25 may be combined with any of aspects 26-33.

Aspect 1. A solids delivery ampoule, comprising:

an ampoule body and a lid defining an interior space, the interior space containing one or more solids support, each solids support configured to support a quantity of a sublimation solid;

a vapor outlet port;

one or more level sensor port; and

one or more level sensor, each of the one or more level sensors extending through the one or more level sensor port into the interior space,

wherein each of the one or more level sensors measures the quantity of the sublimation solid in each solids support.

Aspect 2. The solids delivery ampoule according to aspect 1, wherein the one or more level sensors are selected from a reed switch sensor, an optical sensor, an ultrasonic sensor, a capacitance sensor, an infrared sensor, or a radar sensor.

Aspect 3. The solids delivery ampoule according to any of aspects 1-2, wherein the one or more level sensors each are a reed switch sensor comprising a magnetic disc, and a rod, wherein the rod includes one or more reed switches and the magnetic disc rests on a surface of the quantity of sublimation solid measured by the level sensor.

Aspect 4. The solids delivery ampoule according to aspect 3, wherein the rod of each of the reed switch sensors includes at least two reed switches.

Aspect 5. The solids delivery ampoule according to any of aspects 1-4, wherein the one or more solids supports is a tray.

Aspect 6. The solids delivery ampoule according to any of aspects 1-5, wherein the one or more solids supports are one or more spaces in a tray defined by one or more dividers.

Aspect 7. The solids delivery ampoule according to any of aspects 1-6, further comprising one or more vent tubes configured to convey vapor upwards from at least one of the one or more solids supports.

Aspect 8. The solids delivery ampoule according to any of aspects 1-2, wherein the one or more solids supports are one or more trays.

Aspect 9. The solids delivery ampoule according to aspect 8, wherein the one or more level sensors measure quantities of the sublimation solid in one or more trays selected from the one or more trays, wherein the one or more trays are selected based on a rate of consumption of the sublimation solids in each of the one or more trays.

Aspect 10. The solids delivery ampoule according to aspect 9, wherein the rate of consumption of the sublimation solids is determined based on the sublimation solid and a temperature applied to the solids delivery ampoule when providing a vapor of the sublimation solid.

Aspect 11. The solids delivery ampoule according to any of aspects 8-10, wherein the solids delivery ampoule includes fewer level sensors than a number of trays of the one or more trays.

Aspect 12. The solids delivery ampoule according to any of aspects 1-11, further comprising a carrier gas inlet.

Aspect 13. The solids delivery ampoule according to any of aspects 1-12, wherein the one or more level sensor port is one or more level sensor ports, and the one or more level sensor ports are all distributed along one straight line.

Aspect 14. The solids delivery ampoule according to any of aspects 1-13, wherein the one or more level sensor port is one or more level sensor ports, and the one or more level sensor ports are all distributed such that the one or more level sensor ports do not form one straight line

Aspect 15. The solids delivery ampoule according to any of aspects 1-14, further comprising a controller configured to:

receive a level signal from each of the one or more level sensors; and

determine whether the solids delivery ampoule is to be replaced based on the level signals received from each of the one or more level sensors.

Aspect 16. The solids delivery ampoule according to aspect 15, wherein the controller is further configured to direct the presentation of a message when the solids delivery ampoule is to be replaced.

Aspect 17. The solids delivery ampoule according to any of aspects 15-16, wherein the controller is further configured to direct a heater to pre-heat another ampoule.

Aspect 18. The solids delivery ampoule according to any of aspects 15-17, wherein the controller is further configured to direct an automatic switching from the solids delivery ampoule to another ampoule.

Aspect 19. The solids delivery ampoule according to any of aspects 15-18, wherein the controller is further configured to direct a purge sequence or a cooldown sequence to be performed on the solids delivery ampoule.

Aspect 20. A method of preparing a solids delivery ampoule, comprising:

providing a solids delivery ampoule, the solids delivery ampoule including:
an ampoule body defining an internal space containing one or more solids support,
a vapor outlet port, and
one or more level sensor port;

adding one or more sublimation solids to each of the one or more solids supports; and

providing a level sensor through each of the one or more level sensor ports.

Aspect 21. The method according to aspect 20, wherein the level sensor is a reed switch sensor including a rod and a magnetic disc, and providing the level sensor includes placing the magnetic disc on a surface of one of the one or more sublimation solids.

Aspect 22. The method according to any of aspects 20-21, wherein providing the level sensor through each of the one or more level sensor ports is performed under positive pressure.

Aspect 23. The method according to any of aspects 20-22, further comprising sealing the solids delivery ampoule.

Aspect 24. The method according to any of aspects 20-23, wherein there are fewer level sensor ports than solids supports.

Aspect 25. The method according to aspect 24, wherein the level sensors are provided to one or more solids supports, the one or more solids supports selected based on a rate of consumption of the sublimation solid for each of the solids supports.

Aspect 26. A method of delivering a vapor, comprising:

heating a solids delivery ampoule;

measuring a level of a sublimation solid in a solids support via a level sensor located within the solids delivery ampoule; and

providing a message based the level of the sublimation solid.

Aspect 27. The method according to aspect 26, further comprising providing a flow of a carrier gas into the solids delivery ampoule.

Aspect 28. The method according to any of aspects 26-27, wherein the level sensor is a reed switch sensor including a magnetic disc and one or more reed switches disposed on a rod.

Aspect 29. The method according to any of aspects 26-28, further comprising measuring a second level of the sublimation solid in a second solids support via a second level sensor located within the solids delivery ampoule, and wherein the alert is further based on the second level of the second sublimation solid.

Aspect 30. The method according to any of aspects 26-29, wherein the solids delivery ampoule comprises a plurality of solids supports, and one or more solids supports where the level of the sublimation solid is measured are selected based on a predicted consumption of each of the one or more sublimation solids.

Aspect 31. The method according to any of aspects 26-30, wherein the message includes an alert provided to a user.

Aspect 32. The method according to any of aspects 26-31, wherein the message includes a command directing a heater to pre-heat another ampoule.

Aspect 33. The method according to any of aspects 26-32, wherein the message includes a command directing an automatic switching from the solids delivery ampoule to another ampoule.

Aspect 34. The method according to any of aspects 26-33, wherein the message includes a command directing a purge sequence or a cooldown sequence to be performed on the solids delivery ampoule.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A solids delivery ampoule, comprising:
an ampoule body and a lid defining an interior space, the interior space containing one or more solids support, each solids support configured to support a quantity of a sublimation solid;
a vapor outlet port;
one or more level sensor port; and
one or more level sensor, each of the one or more level sensors extending through the one or more level sensor port into the interior space,
wherein each of the one or more level sensors measures the quantity of the sublimation solid in each solids support.

2. The solids delivery ampoule of claim 1, wherein the one or more level sensors are selected from a reed switch sensor, an optical sensor, an ultrasonic sensor, a capacitance sensor, an infrared sensor, or a radar sensor.

3. The solids delivery ampoule of claim 1, wherein the one or more level sensors each are a reed switch sensor comprising a magnetic disc, and a rod, wherein the rod includes one or more reed switches and the magnetic disc rests on a surface of the quantity of sublimation solid measured by the level sensor.

4. The solids delivery ampoule of claim 1, wherein the one or more solids supports is a tray.

5. The solids delivery ampoule of claim 1, wherein the one or more solids supports are one or more spaces in a tray defined by one or more dividers.

6. The solids delivery ampoule of claim 1, further comprising one or more vent tubes configured to convey vapor upwards from at least one of the one or more solids supports.

7. The solids delivery ampoule of claim 1, wherein the one or more solids supports are one or more trays.

8. The solids delivery ampoule of claim 1, further comprising a carrier gas inlet.

9. The solids delivery ampoule of claim 1, wherein the one or more level sensor port is one or more level sensor ports, and the one or more level sensor ports are all distributed along one straight line.

10. The solids delivery ampoule of claim 1, wherein the one or more level sensor port is one or more level sensor ports, and the one or more level sensor ports are all distributed such that the one or more level sensor ports do not form one straight line.

11. The solids delivery ampoule of claim 1, further comprising a controller configured to:
receive a level signal from each of the one or more level sensors; and
determine whether the solids delivery ampoule is to be replaced based on the level signals received from each of the one or more level sensors.

12. A method of preparing a solids delivery ampoule, comprising:
providing a solids delivery ampoule, the solids delivery ampoule including:
an ampoule body defining an internal space containing one or more solids support,
a vapor outlet port, and
one or more level sensor port;
adding one or more sublimation solids to each of the one or more solids supports; and
providing a level sensor through each of the one or more level sensor ports.

13. The method of claim 12, wherein the level sensor is a reed switch sensor including a rod and a magnetic disc, and providing the level sensor includes placing the magnetic disc on a surface of one of the one or more sublimation solids.

14. The method of claim 12, wherein providing the level sensor through each of the one or more level sensor ports is performed under positive pressure.

15. The method of 12, further comprising sealing the solids delivery ampoule.

16. A method of delivering a vapor, comprising:
heating a solids delivery ampoule;
measuring a level of a sublimation solid in a solids support via a level sensor located within the solids delivery ampoule; and
providing a message based the level of the sublimation solid.

17. The method of claim 16, further comprising providing a flow of a carrier gas into the solids delivery ampoule.

18. The method of claim 16, wherein the level sensor is a reed switch sensor including a magnetic disc and one or more reed switches disposed on a rod.

19. The method of claim 16, further comprising measuring a second level of the sublimation solid in a second solids support via a second level sensor located within the solids delivery ampoule, and wherein the alert is further based on the second level of the second sublimation solid.

20. The method of claim 16, wherein the solids delivery ampoule comprises a plurality of solids supports, and one or more solids supports where the level of the sublimation solid is measured are selected based on a predicted consumption of each of the one or more sublimation solids.
